(19) United States
(12) Patent Application Publication
(10) Pub. No.: US 2025/0095706 A1
(43) Pub. Date: Mar. 20, 2025

(54) SEMICONDUCTOR STORAGE DEVICE

(71) Applicant: Kioxia Corporation, Tokyo (JP)

(72) Inventor: Hiroaki MAEKAWA, Yokohama Kanagawa (JP)

(21) Appl. No.: 18/883,314

(22) Filed: Sep. 12, 2024

(30) Foreign Application Priority Data
Sep. 20, 2023 (JP) 2023-152329

(51) Int. Cl. G11C 11/16

(52) U.S. Cl. CPC G11C 11/1673; G11C 11/161; G11C 11/1675; G11C 11/1677

(57) ABSTRACT

A semiconductor storage device includes a memory cell and a control circuit. In an overall read operation, the control circuit performs a first read operation to detect a first voltage and determine first data from the detected first voltage, writes second data to the memory cell, performs a second read operation to detect a second voltage and determine the second data from the detected second voltage, and compares the first data and the second data based on the first voltage and the second voltage to determine a value of the first data. When the first data and the second data are different, the control circuit performs a sequence of operations that includes a second write operation to write the first data and a verify read operation. Based on third data detected by the verify read operation, the control circuit ends the overall read operation or repeats the sequence of operations.

### CROSS-REFERENCE TO RELATED APPLICATIONS

This application is based upon and claims the benefit of priority from Japanese Patent Application No. 2023-152329, filed Sep. 20, 2023, the entire contents of which are incorporated herein by reference.

### FIELD

Embodiments described herein relate generally to a semiconductor storage device.

### BACKGROUND

A semiconductor storage device that incorporates a variable resistance element as a storage element has been known.

### BRIEF DESCRIPTION OF THE DRAWINGS

FIG. 1 is a block diagram illustrating an example of the overall configuration of a memory system with a semiconductor storage device according to a first embodiment.

FIG. 2 is a circuit diagram illustrating an example of a circuit configuration of a memory cell array incorporated in the semiconductor storage device according to the first embodiment.

FIG. 3 is a perspective view illustrating an example of a structure of the memory cell array incorporated in the semiconductor storage device according to the first embodiment.

FIG. 4 is a sectional view illustrating an example of a sectional structure of a memory cell included in the memory cell array incorporated in the semiconductor storage device according to the first embodiment.

FIG. 5 is a graph illustrating an example of characteristics of the memory cell included in the memory cell array incorporated in the semiconductor storage device according to the first embodiment.

FIG. 6 is a block diagram illustrating an example of a configuration of a read circuit incorporated in the semiconductor storage device according to the first embodiment.

FIG. 7 is a circuit diagram illustrating an example of a circuit configuration of a pre-amplifier included in the read circuit incorporated in the semiconductor storage device according to the first embodiment.

FIG. 8 is a circuit diagram illustrating an example of a circuit configuration of a sense amplifier included in the read circuit incorporated in the semiconductor storage device according to the first embodiment.

FIG. 9 is a flow chart illustrating an example of a sequence of a read operation in the semiconductor storage device according to the first embodiment.

FIG. 10 is a diagram illustrating an overview of a method of data validation in the read operation in the semiconductor storage device according to the first embodiment.

FIG. 11 is a schematic diagram illustrating an example of variation of voltage applied to the memory cell in the read operation in the semiconductor storage device according to the first embodiment.

FIG. 12 is a schematic diagram illustrating an example of variation of voltage applied to the memory cell when a writeback occurs in the read operation in a comparative example.

FIG. 13 is a schematic diagram illustrating an example of variation of voltage applied to the memory cell when a writeback occurs in the read operation in a first modification.

FIG. 14 is a schematic diagram illustrating an example of variation of voltage applied to the memory cell when a writeback occurs in the read operation in a second modification.

FIG. 15 is a schematic diagram illustrating an example of variation of voltage applied to the memory cell when a writeback occurs in the read operation in a third modification.

FIG. 16 is a schematic diagram illustrating an example of variation of voltage applied to the memory cell when a writeback occurs in the read operation in a fourth modification.

FIG. 17 is a schematic diagram illustrating an example of variation of voltage applied to the memory cell when a writeback occurs in the read operation in a fifth modification.

FIG. 18 is a schematic diagram illustrating an example of variation of voltage applied to the memory cell when a writeback occurs in the read operation in a sixth modification.

FIG. 19 is a flow chart illustrating an example of a sequence of the read operation in a semiconductor storage device according to a second embodiment.

FIG. 20 is a graph illustrating an example of the relation between write currents and the write error rate in the semiconductor storage device according to the second embodiment.

### DETAILED DESCRIPTION

Embodiments improve reliability of data written in a memory cell.

In general, according to one embodiment, a semiconductor storage device includes a memory cell and a control circuit. The memory cell includes a switching element and a variable resistance element. The control circuit is configured to, as part of performing an overall read operation: perform a first read operation on the memory cell to detect a first voltage and determine first data stored in the memory cell from the detected first voltage, perform a first write operation on the memory cell after the first read operation to write second data to the memory cell, perform a second read operation on the memory cell after the first write operation to detect a second voltage and determine the second data stored in the memory cell from the detected second voltage, and compare the first data and the second data based on the first voltage and the second voltage to determine a value of the first data. As part of the overall read operation, the control circuit is further configured to perform a sequence of operations when the first data and the second data are different, the sequence of operations including a second write operation on the memory cell to write the first data to the memory cell, and a verify read operation performed on the memory cell after the second write operation that detects a third voltage and determines third data stored in the memory cell from the detected third voltage. As part of the overall read operation, the control circuit is further configured to compare either the first data and the third data based on the first voltage and the third voltage or the second data and the third data based on the second voltage and the third voltage, end the overall read operation when the first data and the third data are the same or when the second data and the third data are different, and repeat the sequence of operations when the first data and the third data are different or when the second data and the third data are the same.

The embodiments will now be described with reference to drawings. The drawings referenced below are schematic or conceptual. The dimensions, ratios, and the like in each of the drawings may not necessarily match the actual ones. In the following description, those components that have substantially the same functionality and configuration have like reference labels. The numerals or the like that follow characters constituting the same reference labels are used to distinguish between elements that have a similar configuration. When it is not necessary to distinguish the elements indicated by the same reference labels from each other, these elements are referenced by their reference labels without referencing the additional numerals or the like.

Note that as used in the specification, the term “connection” indicates that connection is established electrically and does not exclude another element interposed in between. When placed into an ON state, the transistor or the switching circuit is placed into a conductive state between one end and an opposite end. An OFF state of the transistor or the switching circuit does not exclude a flow of a minute current such as a leakage current. “H” level is a voltage level at which an N-type transistor is placed into an ON state when the voltage is applied to the gate end thereof and a P-type transistor is placed into an OFF state when the voltage is applied to the gate end thereof. “L” level is a voltage level at which an N-type transistor is placed into an OFF state when the voltage is applied to the gate end thereof and a P-type transistor is placed into an ON state when the voltage is applied to the gate end thereof.

### <1> First Embodiment

The first embodiment relates to a semiconductor storage device 1 that performs a self-referencing read operation. The semiconductor storage device 1 according to the first embodiment performs verify read after writeback write in the self-referencing read operation. The semiconductor storage device 1 according to the first embodiment will now be described in detail.

### <1-1> Configuration

First, the configuration of the semiconductor storage device 1 according to the first embodiment will be described.

### <1-1-1> Overall Configuration of Memory System MS

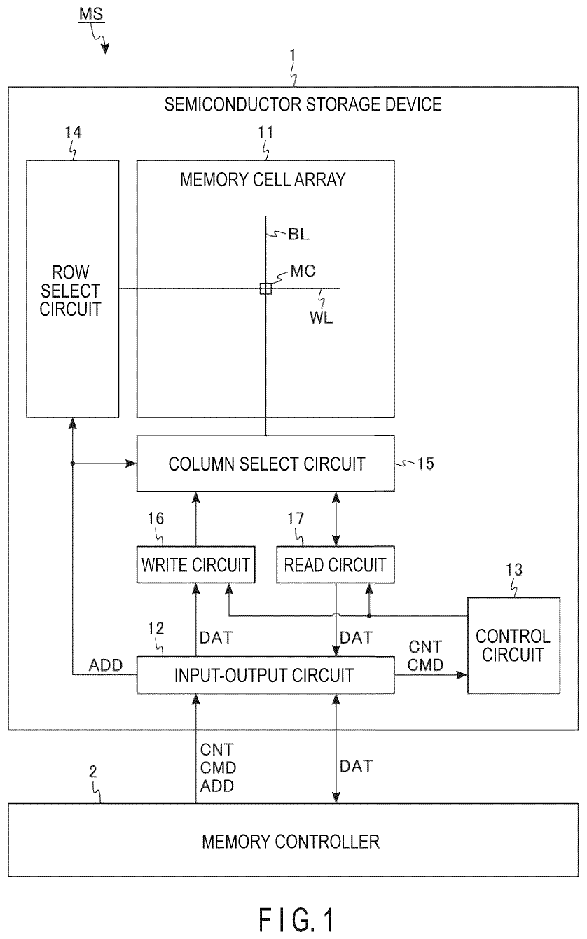

FIG. 1 is a block diagram illustrating an example of the overall configuration of a memory system MS with the semiconductor storage device 1 according to the first embodiment. As illustrated in FIG. 1, the memory system MS includes the semiconductor storage device 1 and a memory controller 2. The semiconductor storage device 1 operates under control of the memory controller 2. The memory controller 2 may instruct the semiconductor storage device 1 for read operation, write operation, or the like, in response to a request (instruction) from external host equipment.

The semiconductor storage device 1 is, for example, a Magnetoresistive Random Access Memory (MRAM). An MRAM is a storage device that incorporates Magnetic Tunnel Junction (MTJ) elements for memory cells and is one type of variable resistance memories. An MTJ element takes advantage of a magnetoresistance effect produced by a magnetic tunnel junction. The MTJ element is also referred to as a magnetoresistance effect element. The semiconductor storage device 1 includes, for example, a memory cell array 11, an input-output circuit 12, a control circuit 13, a row select circuit 14, a column select circuit 15, a write circuit 16, and a read circuit 17.

The memory cell array 11 includes a plurality of memory cells MC, a plurality of word lines WL, and a plurality of bit lines BL. In FIG. 1, a set of a memory cell MC, a word line WL, and a bit line BL is illustrated from among a plurality of memory cells MC, a plurality of word lines WL, and a plurality of bit lines BL. The memory cell MC can store data in a non-volatile manner. The memory cell MC is connected between one word line WL and one bit line BL, and is associated with a set of row and column. A row address is assigned to a word line WL. A column address is assigned to a bit line BL. One or more memory cells MC are identified by selecting one row and selecting one or more columns.

The input-output circuit 12 is connected to the memory controller 2 and governs communication between the semiconductor storage device 1 and the memory controller 2. The input-output circuit 12 transfers a control signal CNT and a command CMD that are received from the memory controller 2 to the control circuit 13. The input-output circuit 12 transfers a row address and a column address included in an address signal ADD received from the memory controller 2 to the row select circuit 14 and column select circuit 15, respectively. The input-output circuit 12 transfers data DAT (write data) received from the memory controller 2 to the write circuit 16. The input-output circuit 12 transfers data DAT (read data) received from the read circuit 17 to the memory controller 2.

The control circuit 13 controls the overall operation of the semiconductor storage device 1. For example, the control circuit 13 performs read operation or write operation based on a control indicated by the control signal CNT and a command CMD. In the write operation, the control circuit 13 supplies a voltage used for writing data to the write circuit 16. In the read operation, the control circuit 13 supplies a voltage used for reading data to the read circuit 17.

The row select circuit 14 is connected to a plurality of word lines WL. Then, the row select circuit 14 selects only one word line WL that is identified with a row address. The selected word line WL is to be electrically connected to a driver circuit (not illustrated), for example.

The column select circuit 15 is connected to a plurality of bit lines BL. Then, the column select circuit 15 selects one or more bit lines BL that are identified with a column address. The selected bit lines BL are to be electrically connected to a driver circuit (not illustrated), for example.

The write circuit 16 supplies a voltage used for writing data to the column select circuit 15 under control of the control circuit 13 and based on data DAT (write data) received from the input-output circuit 12. When a current based on the write data flows through the memory cell MC, the desired data is written to the memory cell MC.

The read circuit 17 includes a plurality of sense amplifiers. The read circuit 17 supplies a voltage used for reading data to the column select circuit 15 under control of the control circuit 13. Then, each sense amplifier validates the data stored in the memory cell MC based on the voltage or the current on the selected bit line BL. The read circuit 17 then transfers data DAT (read data) corresponding to a validation result to the input-output circuit 12.

### <1-1-2> Configuration of Memory Cell Array 11

The configuration of the memory cell array 11 will now be described. Note that in the following description, description will be provided for the case in which the semiconductor storage device 1 is an MRAM.

### (1: Circuit Configuration of Memory Cell Array 11)

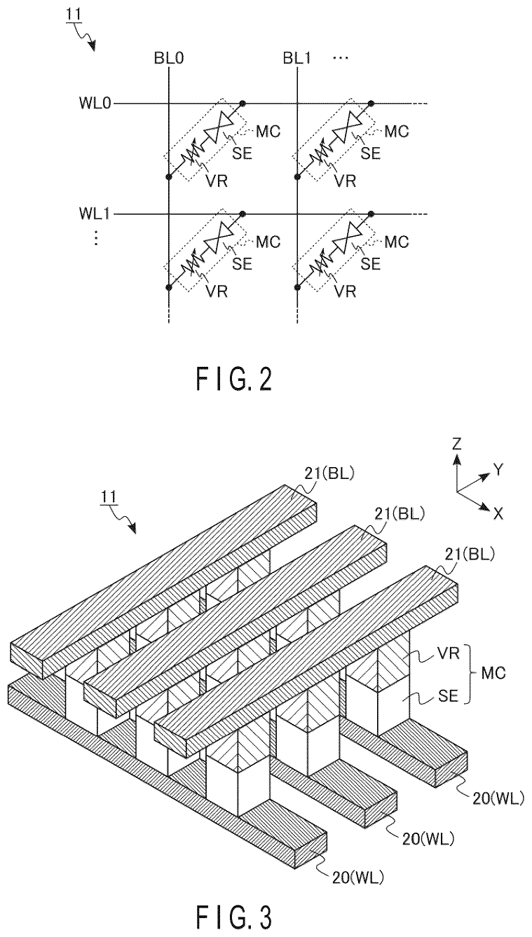

FIG. 2 is a circuit diagram illustrating an example of a circuit configuration of the memory cell array 11 incorporated in the semiconductor storage device 1 according to the first embodiment. FIG. 2 illustrates two word lines WL0 and WL1 derived from among a plurality of word lines WL and two bit lines BL0 and BL1 from among a plurality of bit lines BL. As illustrated in FIG. 2, in the memory cell array 11, a plurality of bit lines BL intersect with a plurality of word lines WL. Then, a memory cell MC is arranged at an intersecting portion of a bit line BL and a word line WL. That is, a plurality of memory cells MC are arranged in a matrix. Specifically, there is a respective memory cell MC connected between lines WL0 and BL0, lines WL0 and BL1, lines WL1 and BL0, and lines WL1 and BL1.

Each memory cell MC includes a variable resistance element VR and a switching element SE. The switching element SE is a two-terminal switching element. The two-terminal switching element is different from a three-terminal switching element such as a transistor in that it does not include the third terminal. The variable resistance element VR and the switching element SE are connected in series between the associated bit and word lines BL and WL. For example, one end of the variable resistance element VR is connected to the associated bit line BL. An opposite end of the variable resistance element VR is connected to one end of the switching element SE. An opposite end of the switching element SE is connected to the associated word line WL.

The resistance state of the variable resistance element VR may change in response to a current flowing through the variable resistance element VR. Then, the variable resistance element VR stores data in a non-volatile manner based on the resistance state (resistance value). For example, the memory cell MC that includes the variable resistance element VR in a high resistance state stores data “1.” The memory cell MC that includes the variable resistance element VR in a low resistance state stores data “0.” Note that the assignment of data associated with a resistance value of the variable resistance element VR may be set in any other way. In the case in which the semiconductor storage device 1 is an MRAM, a magnetoresistance effect element is used as the variable resistance element VR.

The switching element SE controls the supply of a current to the variable resistance element VR. Specifically, the switching element SE is placed into an OFF state when a voltage that is lower than a threshold voltage of the switching element SE is applied to the memory cell MC, and placed into an ON state when a voltage not lower than the threshold voltage of the switching element SE is applied to the memory cell MC. The switching element SE in an OFF state functions as an insulator that has a large resistance value. The switching element SE in an OFF state prevents a current from flowing in the variable resistance element VR. The switching element SE in an ON state functions as a conductor that has a low resistance value. A current flows in the variable resistance element VR connected in series to the switching element SE in an ON state. A bidirectional diode is used as the switching element SE, for example. A transistor or any other elements may be used as the switching element SE.

### (2: Structure of Memory Cell Array 11)

An example of the structure of memory cell array 11 in the first embodiment will now be described. In the following description, the XYZ Cartesian coordinate system is used. The X-direction corresponds to the extending direction of the word line WL. The Y-direction corresponds to the extending direction of the bit line BL. The Z-direction is a direction intersecting each of the X-direction and the Y-direction, and corresponds to the direction perpendicular to a surface of a substrate incorporated in the semiconductor storage device 1. A reference indicative of “lower” and derived and related words thereof denote a position indicated by smaller coordinates on the Z-axis. A reference indicative of “upper” and derived and related words thereof denote a position indicated by larger coordinates on the Z-axis. In a perspective view, a hatching is applied as needed. The hatching applied to a perspective view does not relate to any material or characteristics of a component to which the hatching is applied. In a perspective view and a sectional view, some configurations such as an interlayer dielectric are not illustrated.

FIG. 3 is a perspective view illustrating an example of the structure of the memory cell array 11 incorporated in the semiconductor storage device 1 according to the first embodiment. As illustrated in FIG. 3, the memory cell array 11 includes a plurality of conductor layers 20 and a plurality of conductor layers 21.

A plurality of conductor layers 20 each have portions extending in the X-direction, which are separated from each other. The portions extending in the X-direction of a plurality of conductor layers 20 are arranged side by side in the Y-direction. Each conductor layer 20 is used as a word line WL. A plurality of conductor layers 21 are provided above a wiring layer on which a plurality of conductor layers 20 are provided. A plurality of conductor layers 21 each have portions extending in the Y-direction, which are separated from each other. The portions extending in the Y-direction of a plurality of conductor layers 21 are arranged side by side in the X-direction. Each conductor layer 21 is used as a bit line BL.

In top plan view of FIG. 3, a memory cell MC is arranged at each portion where a conductor layer 20 intersects with a conductor layer 21. Each memory cell MC is prepared in a columnar shape that extends in the Z-direction. In the example, the bottom surface of the memory cell MC is in contact with the conductor layer 20, and the top surface of the memory cell MC is in contact with the conductor layer 21. Specifically, in the example, the switching element SE is provided on the conductor layer 20. The variable resistance element VR is provided on the switching element SE. The conductor layer 21 is provided on the variable resistance element VR.

Note that although the case in which the variable resistance element VR is provided above the switching element SE has been illustrated, this is not a limitation. Depending on the circuit configuration of the memory cell array 11, the variable resistance element VR may be provided below the switching element SE. There may be any other elements or conductor layers inserted between the memory cell MC and the conductor layer 20. Similarly, there may be any other elements or conductor layers inserted between the memory cell MC and the conductor layer 21. Each of the conductor layers 20 and 21 may be referred to as a “wiring.”

### (3: Structure of Memory Cell MC)

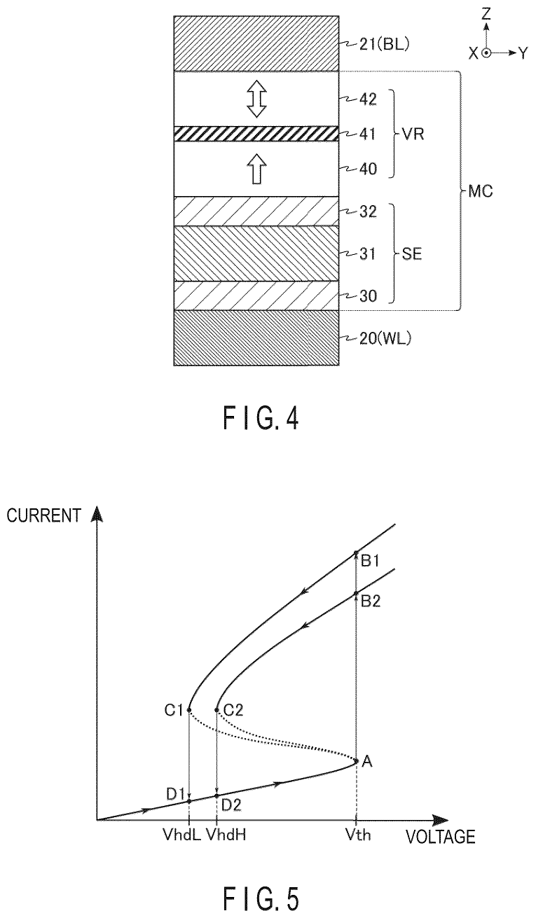

FIG. 4 is a sectional view illustrating an example of the sectional structure of the memory cell MC included in the memory cell array 11 incorporated in the semiconductor storage device 1 according to the first embodiment. As illustrated in FIG. 4, the memory cell MC has a structure in which, for example, a lower electrode 30, a selector material layer 31, an upper electrode 32, a ferromagnetic layer 40, a non-magnetic layer 41, and a ferromagnetic layer 42 are stacked in order from the bottom. A set of the lower electrode 30, the selector material layer 31, and the upper electrode 32 corresponds to the switching element SE. A set of the ferromagnetic layer 40, the non-magnetic layer 41, and the ferromagnetic layer 42 corresponds to the variable resistance element VR.

Each of the ferromagnetic layers 40 and 42 is made of a ferromagnetic material, and has a magnetization direction vertical to a film surface. In an MRAM, for example, the magnetization direction of the ferromagnetic layer 40 is fixed and the magnetization direction of the ferromagnetic layer 42 is variable. In this case, the ferromagnetic layer 40 functions as a reference layer of the MTJ element and the ferromagnetic layer 42 functions as a storage layer of the MTJ element. The non-magnetic layer 41 is made of an insulator such as MgO, and functions as a tunnel barrier layer. The ferromagnetic layers 40 and 42 form a magnetic tunnel junction together with the non-magnetic layer 41. Such variable resistance element VR functions as an MTJ element of a vertical magnetization type, which takes advantage of a tunneling magnetoresistive (TMR) effect.

The variable resistance element VR can be in either a low resistance state or a high resistance state depending on the relative relationship between the magnetization directions of the ferromagnetic layer 40 and the ferromagnetic layer 42. Then, the variable resistance element VR stores data depending on the magnetization direction of the ferromagnetic layer 42 (storage layer). For example, the variable resistance element VR in which the magnetization directions of the reference layer and the storage layer are in an antiparallel state (AP state) is placed in a high resistance state (data “1”). On the other hand, the variable resistance element VR in which the magnetization directions of the reference layer and the storage layer are in a parallel state (P state) is placed in a low resistance state (data “0”).

In the example, the variable resistance element VR is placed in the AP state when a write current is caused to flow in a direction from the ferromagnetic layer 40 toward the ferromagnetic layer 42, and is placed in the P state when a write current is caused to flow in a direction from the ferromagnetic layer 42 toward the ferromagnetic layer 40. The way of write in which a spin torque is induced in the storage layer and the reference layer by causing a write current to flow to the variable resistance element VR in this way so that the magnetization direction of the storage layer is controlled, is referred to as a spin injection write scheme. The variable resistance element VR is configured such that, when a current of a magnitude enough to invert the magnetization direction of the ferromagnetic layer 42 flows in the variable resistance element VR, the magnetization direction of the ferromagnetic layer 40 does not change.

Note that as used in the specification, the expression “the magnetization direction is variable” indicates that a write current causes the magnetization direction to change. The expression “the magnetization direction is fixed” indicates that the write current does not cause the magnetization direction to change. In the variable resistance element VR, the positions of the storage layer and the reference layer may be changed relative to each other. The variable resistance element VR may have any other layers. For example, the variable resistance element VR may have a shift-cancelling layer for suppressing an effect of a leakage magnetic field of the reference layer, a Synthetic Anti-Ferromagnetic (SAF) structure, and the like. Hereinafter, the memory cell MC that includes the variable resistance element VR in an AP state will be referred to as a memory cell MC in an AP state. The memory cell MC that includes the variable resistance element VR in a P state will be referred to as a memory cell MC in a P state.

### (4: Characteristics of Memory Cell MC)

FIG. 5 is a graph illustrating an example of characteristics of a memory cell MC included in the memory cell array 11 incorporated in the semiconductor storage device 1 according to the first embodiment. The horizontal axis of the graph illustrated in FIG. 5 indicates the magnitude of a terminal voltage of the memory cell MC. The vertical axis of the graph illustrated in FIG. 5 indicates, in a logarithmic scale, the magnitude of a current flowing in the memory cell MC. FIG. 5 also indicates, in solid lines, characteristics of the variable resistance element VR of the memory cell MC when it is in a low resistance state and when it is in a high resistance state, and indicates, in dashed lines, imaginary characteristics that do not actually appear in practice.

Note that hereinafter, a terminal voltage of the memory cell MC, that is, the voltage difference across the memory cell MC is also referred to as a “cell voltage.” Furthermore, the current flowing in the memory cell MC is also referred to as a “cell current.” The description below applies to both the cases in which the variable resistance element VR of the memory cell MC is in a low resistance state and in a high resistance state.

When the cell voltage is controlled such that the control circuit 13 increases from 0V, the cell current continues to increase until a threshold voltage Vth of the switching element SE is reached. Until the cell voltage reaches the threshold voltage Vth, the switching element SE of the memory cell MC is off. Then, when the cell voltage reaches the threshold voltage Vth, the switching element SE of the memory cell MC turns on, so that the relationship between the cell voltage and the cell current exhibits discontinuous changes. Specifically, when the cell voltage reaches a point A from 0V, the magnitude of the cell current changes to any one of a point B1 and a point B2 depending on the resistance state of the variable resistance element VR of the memory cell MC. More specifically, the relationship between the cell voltage and the cell current exhibits characteristics indicated at the point B1 when the variable resistance element VR is in the low resistance state, and exhibits characteristics indicated at the point B2 when the variable resistance element VR is in the high resistance state. The magnitudes of the cell current at the point B1 and the point B2 are significantly larger than the magnitude of the cell current at the point A.

When the cell voltage is controlled to decrease from the state in which the cell voltage and the cell current exhibit the relationship indicated at the point B1 or the point B2, the cell current decreases. Then, when the cell voltage is controlled to further decrease and reaches a certain magnitude, the switching element SE of the memory cell MC turns off, so that the relationship between the cell voltage and the cell current exhibits discontinuous changes. At this time, the cell voltage when the relationship between the cell voltage and the cell current starts to exhibit discontinuity depends on the terminal voltage of the variable resistance element VR of the memory cell MC. That is, it depends on whether the variable resistance element VR is in the high resistance state or in the low resistance state. Specifically, when the variable resistance element VR is in the low resistance state, the relationship between the cell voltage and the cell current exhibits discontinuity from a point C1. When the variable resistance element VR is in the high resistance state, the relationship between the cell voltage and the cell current exhibits discontinuity from a point C2.

The relationship between the cell voltage and the cell current exhibits characteristics indicated at a point D1 when the point C1 is reached from the point B1, and exhibits characteristics indicated at a point D2 when the point C2 is reached from the point B2. The magnitude of the cell current at the point D1 is significantly smaller than the magnitude of the cell current at the point C1. Similarly, the magnitude of the cell current at the point D2 is significantly smaller than the magnitude of the cell current at the point C2. The terminal voltage at the point D1 of the memory cell MC that includes the variable resistance element VR in a low resistance state is referred to as a low hold voltage VhdL. The terminal voltage at the point D2 of the memory cell MC that includes the variable resistance element VR in a high resistance state is referred to as a high hold voltage VhdH. The magnitude of the high hold voltage VhdH of each of a plurality of the memory cells MC may vary due to unintended variation of the characteristics of the memory cell MC. The magnitude of the low hold voltage VhdL of each of a plurality of the memory cells MC may vary due to unintended variation of the characteristics of the memory cell MC.

### <1-1-3> Configuration of Read Circuit 17

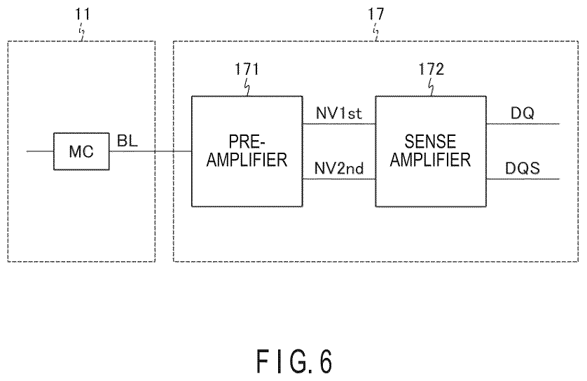

FIG. 6 is a block diagram illustrating an example of the configuration of the read circuit 17 incorporated in the semiconductor storage device 1 according to the first embodiment. As illustrated in FIG. 6, the read circuit 17 includes, for example, a set of a pre-amplifier 171 and a sense amplifier 172. The set of the pre-amplifier 171 and the sense amplifier 172 is associated with one bit line BL.

The pre-amplifier 171 is connected to the associated bit line BL and to each of nodes NV1st and NV2nd. The pre-amplifier 171 is configured to supply a current (cell current) to the memory cell MC such that a voltage based on the cell current can be detected from each of the nodes NV1st and NV2nd independently. Hereinafter, the voltage of the node NV1st will be referred to as “V1st.” The voltage of the node NV2nd will be referred to as “V2nd.”

The sense amplifier 172 is connected to each of the nodes NV1st and NV2nd and to each of nodes DQ and DQS. The sense amplifier 172 is configured to validate data stored in the memory cell MC based on the voltage difference between the nodes NV1st and NV2nd such that a validation result can be output to the nodes DQ and DQS. The voltage of the node DQS when the sense amplifier 172 validates data will be a voltage of an inverse logic level with respect to the node DQ.

Note that the read circuit 17 may have a number of sets of the pre-amplifier 171 and the sense amplifier 172. The set of the pre-amplifier 171 and the sense amplifier 172 may be provided for each bit line BL or may be shared through two or more bit lines BL. When the set of the pre-amplifier 171 and the sense amplifier 172 is shared through two or more bit lines BL, the pre-amplifier 171 is connected to a global bit line. Then, the connection to two or more bit lines BL is achieved through a switching element such that the global bit line can be made electrically continuous in a selective manner.

### (1: Circuit Configuration of Pre-Amplifier 171)

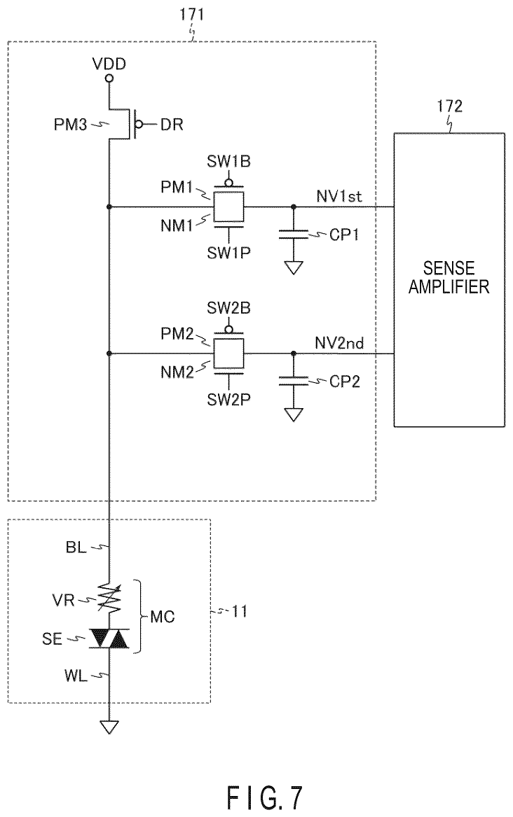

FIG. 7 is a circuit diagram illustrating an example of the circuit configuration of the pre-amplifier 171 included in the read circuit 17 incorporated in the semiconductor storage device 1 according to the first embodiment. FIG. 7 also illustrates the sense amplifier 172 and the memory cell MC associated with one pre-amplifier 171. As illustrated in FIG. 7, the pre-amplifier 171 includes, for example, transistors PM1 to PM3, transistors NM1 and NM2, and capacitors CP1 and CP2. In the specification, the transistor PM is a PMOS transistor. The transistor NM is an NMOS transistor.

The transistors PM1 and NM1 are connected in parallel between the bit line BL and the node NV1st. Specifically, one end of each of the transistors PM1 and NM1 is connected to a bit line BL. An opposite end of each of the transistors PM1 and NM1 is connected to the node NV1st. A gate end of the transistor PM1 is supplied with a control signal SW1B. A gate end of the transistor NM1 is supplied with a control signal SW1P. The control signal SW1B is an inverse logic level signal of the control signal SW1P. The set of transistors PM1 and NM1 functions as one switching element (selector) for controlling whether or not a voltage based on the cell current is to be transferred to the node NV1st.

One electrode of the capacitor CP1 is connected to the node NV1st. The other electrode of the capacitor CP1 is connected to a ground node. A ground voltage is applied to the ground node. When the set of transistors PM1 and NM1 is in an ON state, the capacitor CP1 is charged with a voltage based on the cell current. When the set of transistors PM1 and NM1 is in an OFF state, the capacitor CP1 functions to maintain the voltage of the node NV1st. Then, the voltage of node NV1st (V1st) is supplied to the sense amplifier 172.

The transistors PM2 and NM2 are connected in parallel between the bit line BL and the node NV2nd. Specifically, one end of each of the transistors PM2 and NM2 is connected to a bit line BL. An opposite end of each of the transistors PM2 and NM2 is connected to a node NV2nd. The gate end of the transistor PM2 is supplied with a control signal SW2B. The gate end of the transistor NM2 is supplied with a control signal SW2P. The control signal SW2B is an inverse logic level signal of the control signal SW2P. The set of transistors PM2 and NM2 functions as one switching element (selector) for controlling whether or not a voltage based on the cell current is to be transferred to the node NV2nd.

One electrode of the capacitor CP2 is connected to the node NV2nd. The other electrode of the capacitor CP2 is connected to a ground node. When the set of transistors PM2 and NM2 is in an ON state, the capacitor CP2 is charged with a voltage based on the cell current. When the set of transistors PM2 and NM2 is in an OFF state, the capacitor CP2 functions to maintain the voltage of the node NV2nd. Then, the voltage of the node NV2nd (V2nd) is supplied to the sense amplifier 172.

The transistor PM3 functions as a driver circuit for applying a voltage to the bit line BL. One end of the transistor PM3 is connected to a power supply node. For example, a power supply voltage VDD is applied to the power supply node to which the transistor PM3 is connected. An opposite end of the transistor PM3 is connected to the bit line BL. A gate end of the transistor PM3 is supplied with a control signal DR. For example, the control signal DR is set to “L” level when a voltage is applied to the bit line BL and set to “H” level when a voltage is not applied to the bit line BL.

Note that the circuit configuration of the pre-amplifier 171 may be any other circuit configuration. For example, each of the capacitors CP1 and CP2 is formed from a stray capacity. As long as electrical continuation can be made in a selective manner, there may be any other switching element both between the node NV1st and the bit line BL and between the node NV2nd and the bit line BL. The transistor PM3 may be replaced with another element or circuit. That is, the voltage may be applied to the bit line BL by using any element other than the PMOS transistor.

Note that each of the control signals SW1P, SW1B, SW2P, SW2B, and DR used to control the pre-amplifier 171 is, for example, generated by the control circuit 13. The memory cell MC in the memory cell array 11 illustrated in FIG. 7 corresponds to a state during the read operation. In this case, the memory cell MC is connected to a ground node through the word line WL. When a voltage in the opposite direction is to be applied to the memory cell MC, for example, a voltage is applied to the word line WL through a driver circuit (not illustrated) and the bit line BL is connected to a ground node.

### (2: Circuit Configuration of Sense Amplifier 172)

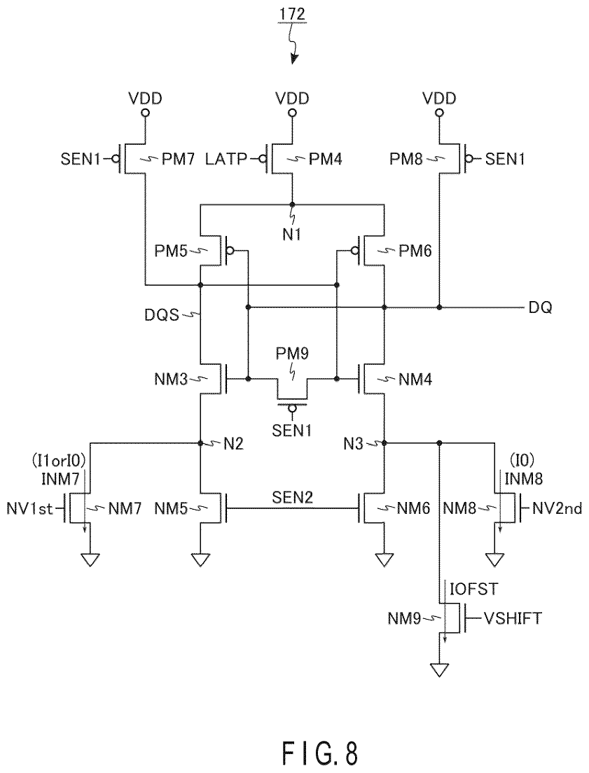

FIG. 8 is a circuit diagram illustrating an example of the circuit configuration of the sense amplifier 172 included in the read circuit 17 incorporated in the semiconductor storage device 1 according to the first embodiment. As illustrated in FIG. 8, the sense amplifier 172 includes, for example, transistors PM4 to PM9, transistors NM3 to NM9, and nodes N1 to N3.

The transistor PM4 has one end connected to a power supply node, an opposite end connected to the node N1, and a gate end to which the control signal LATP is supplied. The transistor PM5 has one end connected to node N1, an opposite end connected to the node DQS, and a gate end connected to the node DQ. The transistor PM6 has one end connected to the node N1, an opposite end connected to the node DQ, and a gate end connected to the node DQS.

The transistor PM7 has one end connected to a power supply node, an opposite end connected to the node DQS, and a gate end to which the control signal SEN1 is supplied. The transistor PM8 has one end connected to a power supply node, an opposite end connected to the node DQ, and a gate end to which the control signal SEN1 is supplied. The transistor PM9 has one end connected to the node DQ, an opposite end connected to the node DQS, and a gate end to which the control signal SEN1 is supplied.

The transistor NM3 has one end connected to the node DQS, and an opposite end connected to the node N2. The transistor NM4 has one end connected to the node DQ, and an opposite end connected to the node N3. The transistor NM5 has one end connected to the node N2, an opposite end connected to a ground node, and a gate end to which the control signal SEN2 is input. The transistor NM6 has one end connected to the node N3, an opposite end connected to a ground node, and a gate end to which the control signal SEN2 is input.

The transistor NM7 has one end connected to the node N2, an opposite end connected to a ground node, and a gate end connected to the node NV1st. That is, a voltage V1st is applied to the gate end of the transistor NM7. The transistor NM8 has one end connected to the node N3, an opposite end connected to a ground node, and a gate end connected to the node NV2nd. That is, a voltage V2nd is applied to the gate end of the transistor NM8. The transistor NM9 has one end connected to the node N3, an opposite end connected to the ground node, and a gate end to which the control signal VSHIFT is supplied.

A set of transistors PM5, PM6, NM3, and NM4 functions as a latch circuit that stores a result of data validation by the sense amplifier 172. For example, when each of the control signals SEN1 and LATP is at “L” level and the control signal SEN2 is at “H” level, the voltages of nodes DQ and DQS reach a similar level, and output of the sense amplifier 172 (voltages of nodes DQ and DQS) are reset. Thereafter, when the control signal SEN1 is controlled to reach “H” level and the control signal SEN2 is controlled to reach “L” level, the latch circuit validates data depending on the magnitude of current flowing in the nodes N2 and N3. The magnitude of the current flowing in the nodes N2 and N3 may change depending on the magnitude of current flowing in each of transistors NM7 and NM8, that is, the magnitude of each of the voltages V1st and V2nd.

Hereinafter, the current flowing in the transistor NM7 will be referred to as “INM7.” The current flowing in the transistor NM8 will be referred to as “INM8.” The current flowing in the transistor NM9 will be referred to as “IOFST.” Each of the transistors NM7 and NM8 allows a current I0 to flow when a voltage based on the cell current corresponding to data “0” is applied to the gate end, and allows a current I1 to flow when a voltage based on the cell current corresponding to data “1” is applied to the gate end. In the self-referencing read operation in the first embodiment, INM7 may be I0 or I1, and INM8 may be I0. The current I0 flowing in the transistor NM7 and the current I0 flowing in the transistor NM8 are substantially the same.

Note that each of the control signals LATP, SEN1, and SEN2 used to control the sense amplifier 172 is, for example, generated by the control circuit 13. In the sense amplifier 172, the power supply voltage VDD is applied to the power supply nodes to which the transistors PM4, PM7, and PM8 are connected, for example. In the sense amplifier 172, a ground voltage VSS is applied to the ground nodes to which the transistors NM5 to NM9 are connected, for example. The circuit configuration of the sense amplifier 172 may be altered as necessary depending on how the self-referencing read operation is achieved. For example, one end of the transistor NM9 may be connected to the node N2, or a transistor used in a similar way to the transistor NM9 may be connected to each of the nodes N2 and N3.

### <1-2> Operation

Next, the operation of the semiconductor storage device 1 according to the first embodiment will be described. Hereinafter, the sequence of the self-referencing read operation performed by the semiconductor storage device 1 according to the first embodiment, a method of data validation, and a specific example will be described in this order.

### <1-2-1> Sequence of Read Operation

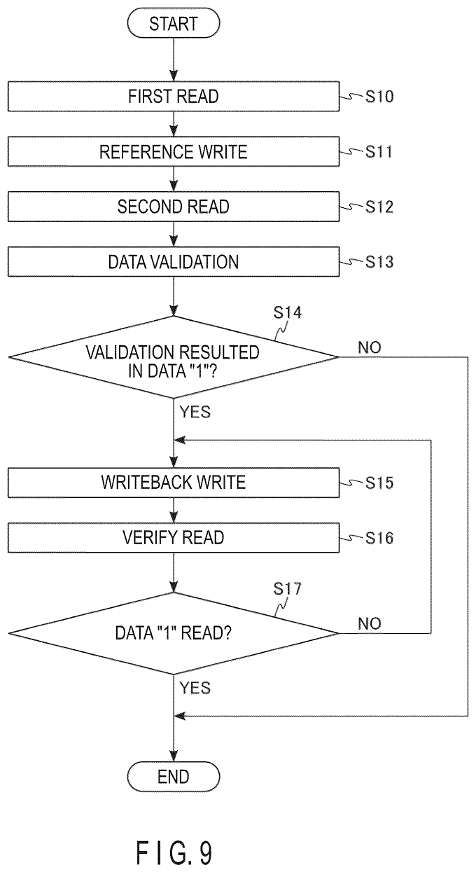

FIG. 9 is a flow chart illustrating an example of the sequence of a read operation in the semiconductor storage device 1 according to the first embodiment.

The control circuit 13 of the semiconductor storage device 1 starts a series of processes in FIG. 9 (START), for example, upon receipt from the memory controller 2 of an indication of a read operation, and of address information of the memory cell MC to be read. The following description of the series of processes corresponds to the processes on the memory cell MC to be read.

First, the control circuit 13 performs first read (S10). The first read is an operation of detecting a voltage based on the cell current flowing from the memory cell MC to the node NV1st of the pre-amplifier 171, and determining data stored in the memory cell MC from the detected voltage. In the first read, the control circuit 13 controls each of the control signals DR, SW1B, and SW2P to reach “L” level, and controls each of the control signals SW1P and SW2B to reach “H” level, so that the word line WL and the ground nodes are electrically connected. Then, the transistors PM3, PM1, and NM1 are placed into an ON state, and transistors PM2 and NM2 are placed into an OFF state. This allows a voltage to be applied to the bit line BL through the transistor PM3, so that the cell current flows through the memory cell MC. Then, the voltage based on the cell current is detected from the node NV1st through the set of transistors PM1 and NM1. Thereafter, the set of transistors PM1 and NM1 is controlled into an OFF state.

Next, the control circuit 13 performs reference write (S11). The reference write is an operation of writing data “0” to the memory cell MC. In the reference write, for example, the control circuit 13 applies a write voltage to the bit line BL and applies a ground voltage to the word line WL. This allows a write current to flow from the bit line BL toward the word line WL through the memory cell MC, so that the data “0” is written to the memory cell MC.

Next, the control circuit 13 performs second read (S12). The second read is an operation of detecting a voltage based on the cell current flowing from the memory cell MC to the node NV2nd of the pre-amplifier 171, and determining data stored in the memory cell MC from the detected voltage. The second read corresponds to reading the data “0.” In the second read, the control circuit 13 controls each of the control signals DR, SW1P, and SW2B to reach “L” level, and controls each of the control signals SW1B and SW2P to reach “H” level, so that the word line WL and the ground nodes are electrically connected. Then, the transistors PM3, PM2, and NM2 are placed into an ON state, and the transistors PM1 and NM1 are placed into an OFF state. This allows a voltage to be applied to the bit line BL through the transistor PM3, so that the cell current flows through the memory cell MC. Then, the voltage based on the cell current is detected from the node NV2nd through the set of transistors PM2 and NM2. Thereafter, the set of transistors PM2 and NM2 is controlled into an OFF state.

Next, the control circuit 13 performs data validation to compare the result of the first read to the result of the second read (S13). In the data validation, the control circuit 13 causes the latch circuit of the sense amplifier 172 to validate data based on the magnitude of a current flowing in each of the nodes N2 and N3. A validation result of data in the example corresponds to an output voltage of the node DQ.

Next, the control circuit 13 determines whether or not the validation result is data “1” in the process of S13 to determine a value of the data determined from the first read, the validation result of data “1” indicating that the results of the first read and the second read are different (S14). When it is determined that the validation result is not the data “1” (S14: NO), the data stored in the memory cell MC before the read operation was the data “0.” Accordingly, the results of the first read and the second read are the same, and the data stored in the memory cell MC before the read operation is still stored, so the control circuit 13 ends the series of processes in FIG. 9 (END). When it is determined that the validation result is data “1” (S14: YES), the data stored in the memory cell MC before the read operation is different from the data “0” that is stored now, and the control circuit 13 proceeds to the process of S15.

In the process of S15, the control circuit 13 performs writeback write. The writeback write is an operation of writing data “1” to the memory cell MC. In the writeback write, the control circuit 13, for example, applies a write voltage to the word line WL, and applies a ground voltage to the bit line BL. This allows a write current to flow from the word line WL toward the bit line BL through the memory cell MC, so that the data “1” is written to the memory cell MC. However, depending on the characteristics of the memory cell MC, one writeback operation may not be enough to change the data stored in the memory cell MC from the data “0” to data “1.”

Next, the control circuit 13 performs verify read (S16). The verify read is an operation of reading the data stored in the memory cell MC subjected to the writeback write. In the verify read, the control circuit 13, for example, performs a similar operation to the first read to detect a voltage based on the cell current to the node NV1st, and determining data stored in the memory cell MC from the detected voltage.

Next, the control circuit 13 determines whether or not data “1” is read in the verify read in the process of the previous S16 (S17). In the process of S17, the control circuit 13 performs data validation similar to the process of S13 to compare the result of the verify read to the result of the second read. When it is determined that data “1” is not read because the results of the verify read and the second read are the same (S17: NO), the control circuit 13 proceeds to the process of S15 to repeat the processes of S15 to S17 again in order. When it is determined that data “1” is read because the results of the verify read and the second read are different (S17: YES), the control circuit 13 determines that enough writeback writes have been performed to store the data “1” in the memory cell MC, and ends a series of processes in FIG. 9 (END).

Note that in the description above, the case in which the data stored in the memory cell MC is validated by comparing the result of the verify read with the result of the second read by the processes of S16 and S17 has been illustrated. This is not a limitation. In the verify read, the control circuit 13 may perform a similar operation to the second read and detect a voltage based on the cell current to the node NV2nd. In this case, the control circuit 13 compares the result of the verify read with the result of the first read to validate the data stored in the memory cell MC. In this case, when the results of the verify read and the first read are the same, the control circuit 13 determines that enough writeback writes have been performed to store the data “1” in the memory cell MC, and to end the series of processes in FIG. 9. When the results of the verify read and the first read are different, the control circuit 13 proceeds to the process of S15 to perform the processes of S15 to S17 again in order.

### <1-2-2> Method of Data Validation

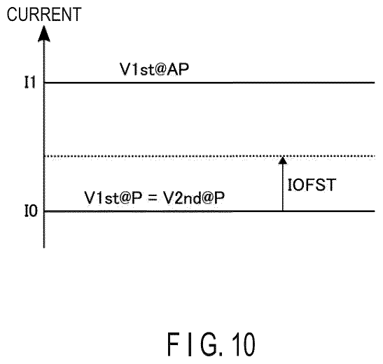

FIG. 10 is a diagram illustrating an overview of a method of data validation in the read operation in the semiconductor storage device 1 according to the first embodiment. FIG. 10 indicates the magnitude of a current relating to the read operation. As illustrated in FIG. 10, the magnitude of the current I1 associated with the data “1” is larger than the current I0 associated with the data “0.” This is because the voltage of the node NV1st or NV2nd based on the cell current of the memory cell MC in an AP state in which the data “1” is stored is larger than the voltage of the node NV1st or NV2nd based on the cell current of the memory cell MC in a P state in which the data “0” is stored.

The self-referencing read operation compares the result of the first read of reading the data stored in the memory cell MC with the result of the second read of reading fixed data stored to the same memory cell MC by performing reference write thereon to validate the data stored in the memory cell MC. However, there are some situations in which different data is read from the first read and the second read even though the same data (e.g., the data “0”) is stored at the times of the first and second reads. This sometimes happens because despite the data stored being the same, there may be a small difference in the currents flowing in nodes N2 and N3 of the sense amplifier 172 illustrated in FIG. 8 at those times, thus leading to a false validation (e.g., determining that the data read from the first read is the data “1” when the data “0” is actually stored in the memory cell MC).

Therefore, according to some embodiments, the transistor NM9 causes an offset current IOFST to flow to the node N3 of the sense amplifier 172 when the sense amplifier 172 is performing the second read. According to such embodiments, the sense amplifier 172 may compare the current in the node N2 for the first read (e.g., I0) to the resulting current in the node N3 for the second read (e.g., I0+IOFST), which is a difference that the sense amplifier 172 is able to accurately detect. In this way, the sense amplifier 172 can correctly read the data of the memory cell MC when the data stored therein is the data “0.”

Note that the method of data validation as described above corresponds to the operation in the case in which the cell current is larger in the memory cell MC in an AP state than in the memory cell MC in a P state, and data “1” (P state) is written to the memory cell MC in the writeback write. A method of data validation by the sense amplifier 172 may be altered as necessary depending on the characteristics of the memory cell MC, the data written to the memory cell MC in the writeback write, or the circuit configurations of the pre-amplifier 171 and the sense amplifier 172. The semiconductor storage device 1 according to the first embodiment may be configured to perform at least one set of writeback write and verify read in a read operation of the self-referencing scheme when data written to the memory cell MC in writeback write is different from the data stored in the memory cell MC before read operation.

### <1-2-3> Specific Example of Read Operation

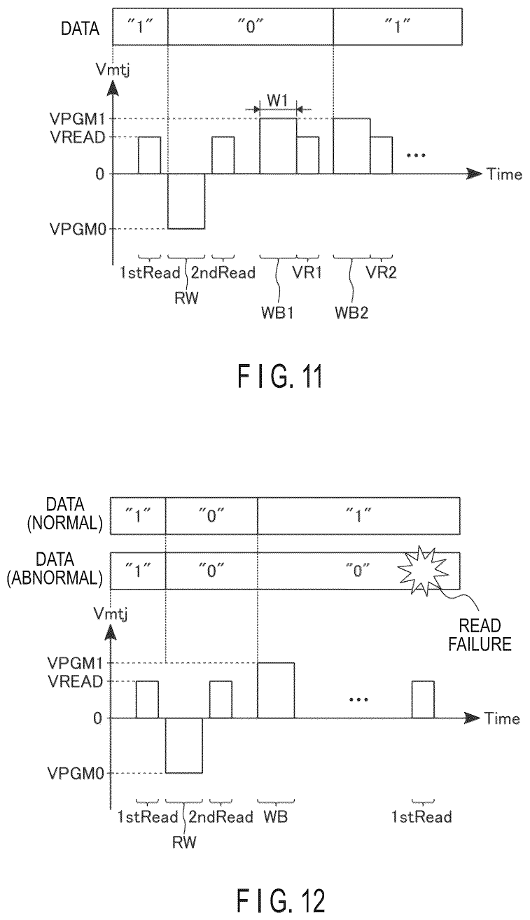

FIG. 11 is a schematic diagram illustrating an example of variation of voltage applied to the memory cell MC when a writeback write occurs in a read operation of the semiconductor storage device 1 according to the first embodiment. An upper part of FIG. 11 illustrates a change in data stored in the memory cell MC to be read. The horizontal axis of the chart illustrated in FIG. 11 indicates time, and vertical axis of the chart indicates an inter-terminal voltage (cell voltage Vmtj) of the memory cell MC. Hereinafter, when the voltage of the bit line BL is higher than the voltage of the word line WL, it is considered that a positive cell voltage Vmtj is applied to the memory cell MC. As illustrated in FIG. 11, in the example, the memory cell MC stores data “1” at the start of the read operation.

In the read operation, first read (1 stRead) is performed first. In the first read, a read voltage VREAD is applied to the memory cell. VREAD is a positive voltage that allows a read current to flow in the memory cell MC.

Next, reference write (RW) is performed. In the reference write, a program voltage VPGM0 is applied to the memory cell MC. VPGM0 is a negative voltage that enables data “0” to be written to the memory cell MC. In this way, the data “0” is written to the memory cell MC.

Next, second read (2ndRead) is performed. In the second read, a read voltage VREAD is applied to the memory cell MC.

Next, the first round of writeback write (WB1) is performed. In the writeback write, a program voltage VPGM1 is applied to the memory cell MC. VPGM1 is a positive voltage that enables data “1” to be written to the memory cell MC. That is, a current and a voltage are applied to the memory cell MC in the opposite direction to the reference write. The pulse width of VPGM1 in the first embodiment is a pulse width W1, which is similar to a program voltage used in the write operation of data “0.” In the example, after the first round of writeback write is performed, the memory cell MC still stores data “0.”

Then, immediately after the first round of writeback write, the first round of verify read (VR1) is performed. In the verify read, a read voltage VREAD is applied to the memory cell MC. In the example, since data “0” is read in the first round of verify read, the control circuit 13 performs the second round of writeback write (WB2) and verify read (VR2) consecutively.

In the example of FIG. 11, when the second round of writeback write is performed, data “1” is written to the memory cell MC. Then, since data “1” is read in the second round of verify read, the control circuit 13 ends the read operation.

As described above, a current and a voltage are applied to the memory cell MC in the same direction in both the first read and the second read. The direction is defined as a “1” direction. Then, in the reference write, a current and a voltage are applied to the memory cell MC in the opposite direction to the “1” direction. The direction is defined as a “0” direction. Since the directions in which a current and a voltage are applied are thus set, false write during read can be prevented. Furthermore, during the reference write, data can be written with a low current.

### <1-3> Advantageous Effects of First Embodiment

According to the semiconductor storage device 1 according to the first embodiment as described above, reliability of data written in the memory cell MC can be improved. Advantageous effects of the first embodiment will now be described in detail.

MRAM is known as a non-volatile memory that is high speed and capable of a low voltage operation. A memory cell MC that has a 1SIM cell structure, in which MTJ elements (variable resistance elements VR) and switching elements SE are stacked, can achieve a large capacity by large integration and three-dimensional stacking. However, the characteristics of the memory cell MC may vary due to unintended variation.

Accordingly, the self-referencing read operation has been researched as a way of preventing false read despite characteristics variations of the memory cells MC. The self-referencing read operation temporarily destroys the data stored in the memory cell MC when the data stored in the memory cell MC is the data “1.” Then, writeback write is performed after data validation to writeback the destroyed data to the memory cell MC.

FIG. 12 is a schematic diagram illustrating an example of variation of voltage applied to the memory cell MC when a writeback occurs in a read operation in a comparative example. In the read operation in the comparative example, verify read after writeback write is not performed. In this case, as illustrated in FIG. 12, if write failure occurs in the writeback, read failure would occur in the next read operation. As a way of reducing write failure, it is conceivable to write data strongly by using a high program voltage VPGM. However, use of a high program voltage VPGM deteriorates the durability of the memory cell MC and may be a cause of an occurrence of TDDB (Time Dependent Dielectric Breakdown) failure.

On the other hand, the semiconductor storage device 1 according to the first embodiment performs the verify read immediately after the writeback write in the self-referencing read operation. The semiconductor storage device 1 can detect an occurrence of write failure by the verify read and perform writeback write again. As a result, with the semiconductor storage device 1 according to the first embodiment, it is possible to reduce occurrence of read failure in the next read operation and also reduce TDDB failure. Accordingly, the semiconductor storage device 1 according to the first embodiment can improve reliability of data written in the memory cell MC.

### <1-4> Modifications of First Embodiment

Various modifications can be made to the read operation of the semiconductor storage device 1 according to the first embodiment. As modifications to the first embodiment, a first modification to a sixth modification will now be described in order.

### (1: First Modification)

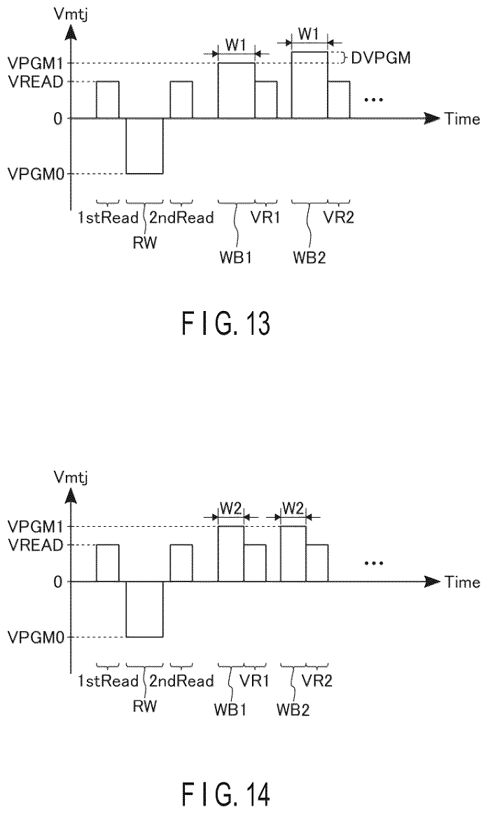

FIG. 13 is a schematic diagram illustrating an example of variation of voltage applied to the memory cell MC when a writeback occurs in the read operation in a first modification. As illustrated in FIG. 13, in the first modification, the control circuit 13 varies a voltage and a current applied to the memory cell MC gradually each time the writeback write is performed. For example, a voltage obtained by adding DVPGM to the program voltage used in the previous writeback write is applied to the memory cell MC whenever the number of writeback writes increases. Specifically, a program voltage VPGM1 is applied to the memory cell MC in the first round of writeback write (WB1) and VPGM1+DVPGM is applied thereto in the second round of writeback write (WB2). Applying the voltage VPGM1+DVPGM increases the likelihood of successfully updating the data stored in the memory cell (MC) without causing the amount of stress induced by high program voltage VPGM. As a result, the first modification may be advantageous for writing data “1” to the memory cell MC while stress on the memory cell MC is still suppressed. Note that the pulse width of the program voltage VPGM1 used in writeback write is, for example, “W1” as in a normal write operation.

### (2: Second Modification)

FIG. 14 is a schematic diagram illustrating an example of variation of voltage applied to the memory cell MC when a writeback occurs in the read operation in a second modification. As illustrated in FIG. 14, in the second modification, the control circuit 13 varies the pulse width of a voltage applied to the memory cell MC in writeback write from that in a normal write operation. For example, the pulse width of the program voltage VPGM1 used in writeback write is set to “W2” that is narrower than that in a normal write operation. This is not a limitation, and the pulse width of the program voltage VPGM1 used in writeback write may be set to be wider than that in a normal write operation, or may be varied every time writeback write is performed. Decreasing the pulse width of the program voltage VPGM1 from W1 to W2 reduces the time required for performing a read operation, without causing the amount of stress induced by high program voltage VPGM. As a result, the second modification may be advantageous for writing data “1” to the memory cell MC while stress on the memory cell MC is suppressed.

### (3: Third Modification)

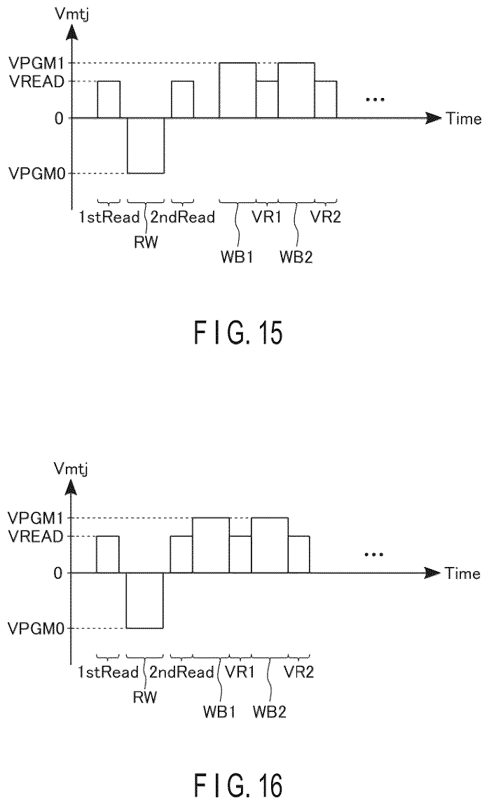

FIG. 15 is a schematic diagram illustrating an example of variation of voltage applied to the memory cell MC when a writeback occurs in the read operation in a third modification. As illustrated in FIG. 15, in the third modification, the control circuit 13 consecutively performs verify read and the next writeback write. Specifically, the control circuit 13 applies read voltage VREAD to the memory cell MC in the first round of verify read (VR1), and thereafter makes a transition of a voltage of the memory cell MC continuously to a program voltage VPGM1 without a transition to 0V. In this way, the third modification can reduce the time for a read operation when a set of the writeback write and the verify read is performed multiple times.

### (4: Fourth Modification)

FIG. 16 is a schematic diagram illustrating an example of variation of voltage applied to the memory cell MC when a writeback occurs in the read operation in the fourth modification. As illustrated in FIG. 16, in the fourth modification, the control circuit 13 consecutively performs the second read and the first round of writeback write. Specifically, the control circuit 13 applies a read voltage VREAD to the memory cell MC in the second read, and thereafter makes a transition of a voltage of the memory cell MC continuously to a program voltage VPGM1 without a transition to 0V. In this way, the fourth modification can reduce the time for a read operation in the first embodiment. Note that FIG. 16 illustrates a case in which the fourth modification and the third modification are combined.

### (5: Fifth Modification)

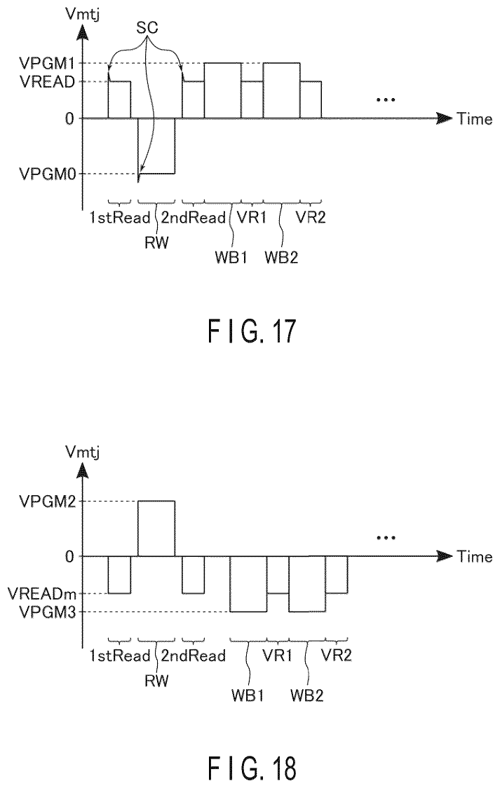

FIG. 17 is a schematic diagram illustrating an example of variation of voltage applied to the memory cell MC when a writeback occurs in the read operation in a fifth modification. In the fifth modification, a snap-back selector is used as a switching element SE. Then, in the fifth modification, as illustrated in FIG. 17, the control circuit 13 performs a read operation in which, for example, the third modification and the fourth modification are combined. In general, when a snap-back selector is used, a spike current SC may occur when the selector turns on. Occurrence of spike current SC may deteriorate the durability of the memory cell MC. However, the fifth modification can reduce how many times the selector turns on and off by a combination of the third modification and the fourth modification, so that the number of occurrences of the spike current SC can be reduced. As a result, with the fifth modification, it is possible to use a snap-back selector as a switching element SE while preventing the durability of the memory cell MC from degrading.

### (6: Sixth Modification)

FIG. 18 is a schematic diagram illustrating an example of variation of voltage applied to the memory cell MC when a writeback occurs in the read operation in a sixth modification. As illustrated in FIG. 18, in the sixth modification, a voltage in the direction opposite to that in the first embodiment is used in a read operation. Specifically, in each of the first read, the second read, and the verify read, a negative read voltage VREADm is applied to the memory cell MC. In the reference write, a program voltage VPGM2 is applied to the memory cell MC. VPGM2 is a positive voltage that enables data “1” to be written to the memory cell MC. In the writeback write, a program voltage VPGM3 is applied to the memory cell MC. VPGM3 is a negative voltage that enables data “0” to be written to the memory cell MC. In this case, in the verify read, the control circuit 13 performs a similar operation to the second read to detect a voltage based on the cell current to the node NV2nd, and compares the result of the verify read with the result of the first read. The sixth modification can produce advantageous effects similar to those in the first embodiment.

### <2> Second Embodiment

The semiconductor storage device 1 according to a second embodiment limits the maximum number of executions of a set of writeback write and verify read in a read operation. The semiconductor storage device 1 according to the second embodiment will now be described with an emphasis on differences from the first embodiment.

### <2-1> Configuration

The configuration of the semiconductor storage device 1 according to the second embodiment is the same as the first embodiment.

### <2-2> Operation

The operation of the semiconductor storage device 1 according to the second embodiment is largely the same as that of the first embodiment except for some parts of a sequence of a read operation.

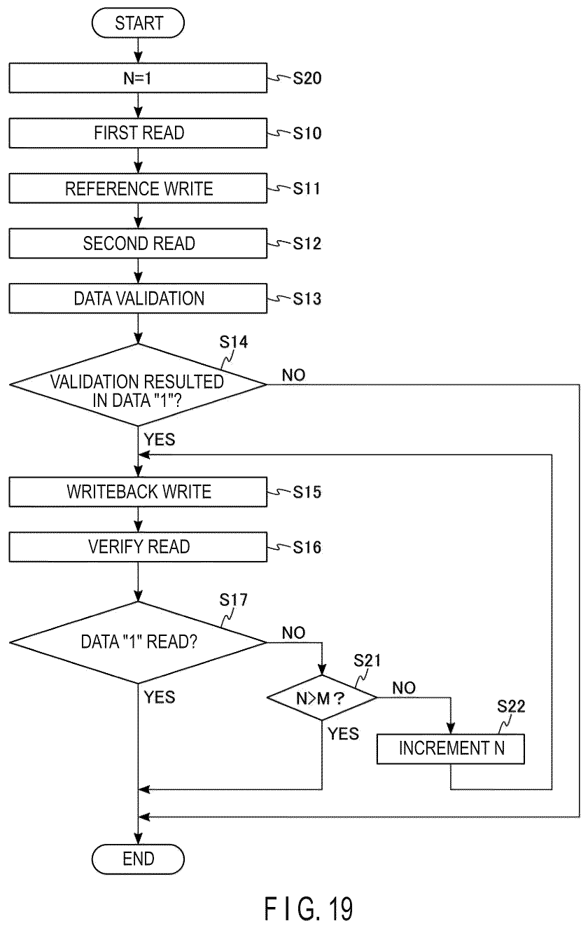

FIG. 19 is a flow chart illustrating an example of a sequence of a read operation in the semiconductor storage device 1 according to the second embodiment. Note that “N” used in the following description is a variable used by the control circuit 13, and corresponds to the number of executions of a set of writeback write and verify read. “M” is a fixed number such as 6 that is predetermined prior to a read operation, and is used to determine the maximum number of executions of a set of writeback write and verify read. In practice, the value of M may vary depending on characteristics of a product performing the second embodiment.

The control circuit 13 of the semiconductor storage device 1 starts a series of processes in FIG. 19 (START), for example, upon receipt from the memory controller 2 of an indication of a read operation, and of address information of the memory cell MC to be read.

First, the control circuit 13 performs processing of “N=1” (S20). That is, the control circuit 13 resets a count of the number of executions of a set of writeback write and verify read at the start of read operation.

Next, the control circuit 13 performs first read as in the first embodiment (S10).

Next, the control circuit 13 performs reference write as in the first embodiment (S11).

Next, the control circuit 13 performs second read as in the first embodiment (S12).

Next, the control circuit 13 performs data validation as in the first embodiment (S13).

Next, the control circuit 13 determines whether or not the validation result in the process of S13 is data “1” as in the first embodiment (S14). When it is determined that the validation result is not data “1” (S14: NO), the control circuit 13 ends a series of processes in FIG. 19 (END). When it is determined that the validation result is data “1” (S14: YES), the control circuit 13 proceeds to the process of S15.

In the process of S15, the control circuit 13 performs writeback write as in the first embodiment.

Next, the control circuit 13 performs verify read as in the first embodiment (S16).

Next, the control circuit 13 determines whether or not data “1” is read in the verify read in the process of the previous S16 as in the first embodiment (S17). When it is determined that data “1” is not read (S17: NO), the control circuit 13 proceeds to the process of S21. When it is determined that data “1” is read (S17: YES), the control circuit 13 ends a series of processes in FIG. 19 (END).

In the process of S21, the control circuit 13 determines whether or not “N>M” is satisfied. When it is determined that “N>M” is not satisfied (S21: NO), the control circuit 13 increments N (S22) and proceeds to the process of S15. That is, the control circuit 13 increases the count of the number of executions of writeback write and verify read and performs the processes of S15 to S17 again in order. When it is determined that “N>M” is satisfied (S21: YES), the control circuit 13 ends a series of processes in FIG. 19 (END).

### <2-3> Advantageous Effects of Second Embodiment

Writeback write may sometimes be performed unlimitedly in a read operation when TDDB failure has occurred. When a memory cell MC in which the TDDB failure occurs is accessed, writeback may be performed unlimitedly because writeback is impossible. When a sequence of writeback is unlimitedly performed, access to other memory cells MC would be interrupted.

In contrast, the semiconductor storage device 1 according to the second embodiment determines the maximum number of executions of a set of writeback write and verify read in advance. As a result, the semiconductor storage device 1 according to the second embodiment can allow other memory cells MC to be accessible even when a memory cell MC in which TDDB failure occurs is accessed. The maximum number of executions of writeback write may be altered as necessary depending on the design of the memory cell MC.

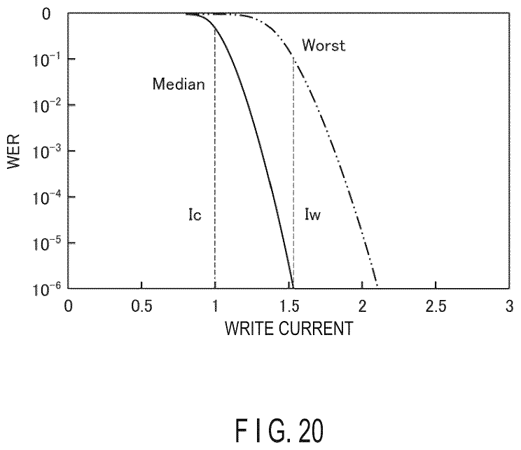

FIG. 20 is a graph illustrating an example of the relation between write currents and the write error rate in the semiconductor storage device according to the second embodiment. The horizontal axis of the graph illustrated in FIG. 20 indicates a magnitude of write current. The vertical axis of the graph illustrated in FIG. 20 indicates the write error rate (WER). Ic corresponds to a write current that has a write probability of 0.5 for a median bit. Iw corresponds to an actual write current. Note that the median bit (Median) corresponds to a memory cell MC that corresponds to a median in its write characteristics. A worst bit (Worst) corresponds to a memory cell MC that is the worst in its write characteristics.

Normally, it is necessary to apply Iw that is approximately 1.5 to 2 times Ic to the memory cell MC to guarantee that write can be achieved to an extent that WER for the worst bit is on the order of 10⁻⁶. In this case, excessive stress is applied on the median bit. In contrast, since a set of writeback write and verify read, which has been described in the first and second embodiments, is performed, writeback is performed under lower stress conditions than during the normal write. As a result, the occurrence of TDDB failure for the worst bit can be reduced. For example, as illustrated in FIG. 20, when WER for the worst memory cell MC in one round of writeback write is 0.1 or less in design, the execution of up to approximately 6 rounds of writeback write may be enough to achieve WER of 1 ppm. In this case, performing 6 rounds of writeback write achieves WER=10⁻⁶ for the worst bit.

### <3> Conclusion

The first modification to the sixth modification described in the first embodiment can be combined as necessary. For example, when the first modification and the second modification are combined, the control circuit 13 may change the pulse width of a program voltage or the magnitude of a program voltage each time a set of writeback write and verify read is performed. Although in the embodiments described above, the case has been illustrated in which the directions of the voltage applied to the memory cell MC are opposite between the first and second read and the reference write, the directions of the voltage applied to the memory cell MC may be the same direction both in the first and second read and the reference write.

Although in the embodiments described above, an MRAM that incorporates MTJ elements of a vertical magnetization type in which the magnetization direction is oriented in a direction vertical to the film surface, has been illustrated as the semiconductor storage device 1, this is not a limitation. The semiconductor storage device 1 may be an MRAM that incorporates MTJ elements of an in-plane magnetization type in which the magnetization direction is oriented in an in-plane direction. The semiconductor storage device 1 may be any variable resistance memories other than the MRAM. With any variable resistance memory other than the MRAM, the application of the embodiments described above can also produce similar advantageous effects. Note that an MRAM tends to have difference in characteristics that is smaller than that of other variable resistance memories between the low resistance state and the high resistance state. Accordingly, the embodiments described above can produce particularly larger advantageous effects when applied to the MRAM.

In the embodiments described above, the bit line BL and the word line WL are in a symmetrical relationship. That is, in the embodiments described above, the bit line BL may be read as the word line WL and the word line WL may be read as the bit line BL. The “0” direction may be referred to as an AP-to-P direction because the memory cell MC makes a transition from the AP state to the P state. The “1” direction may be referred to as a P-to-AP direction because the memory cell MC makes a transition from the P state to the AP state.

In the embodiments described above, the “pulse width” is defined with respect to clock time as a voltage signal rises from an initial level to a maximum level and then falls from the maximum level back to the initial level. Specifically, the pulse width is a time interval between two points: the time during the rise at which the voltage signal is at half of the maximum level and the time during the fall at which the voltage signal returns to half of the maximum level, such measurement known as “full width at half maximum” of the pulse. In the embodiments described above, one end of a transistor corresponds to one of a source end and a drain end of the transistor. Then, an opposite end of a transistor corresponds to the other of the source end and the drain end of the transistor. The correspondence between one end or opposite end and a source end or a drain end may also be varied depending on the type of the transistor (for example, whether the transistor is an NMOS transistor or a PMOS transistor).

### ADDITIONAL REMARKS

The breadth of the invention described herein, as disclosed by this specification, includes the following embodiments.

### Additional Embodiment 1

A method for performing an overall read operation on a memory cell of a semiconductor storage device comprises: performing a first read operation on the memory cell to detect a first voltage and determine first data stored in the memory cell from the detected first voltage; performing a first write operation on the memory cell after the first read operation to write second data to the memory cell; performing a second read operation on the memory cell after the first write operation to detect a second voltage and determine the second data stored in the memory cell from the detected second voltage; comparing the first data and the second data based on the first voltage and the second voltage to determine a value of the first data; determining that the first data and the second data are different; performing a sequence of operations in response to determining that the first data and the second data are different, the sequence of operations including a second write operation on the memory cell to write the first data to the memory cell, and a verify read operation performed on the memory cell after the second write operation that detects a third voltage and determines third data stored in the memory cell from the detected third voltage; comparing either the first data and the third data based on the first voltage and the third voltage or the second data and the third data based on the second voltage and the third voltage; determining that the first data and the third data are the same or that the second data and the third data are different; and ending the overall read operation in response to determining that the first data and the third data are the same or that the second data and the third data are different.

### Additional Embodiment 2

A method for performing an overall read operation on a memory cell of a semiconductor storage device comprises the limitations of Explicitly Included Embodiment 1 and further comprises: varying a program voltage applied to the memory cell in the second write operation depending on how many times the sequence of operations is performed.

### Additional Embodiment 3

A method for performing an overall read operation on a memory cell of a semiconductor storage device comprises the limitations of Explicitly Included Embodiment 1 and further comprises: varying an amount of current caused to flow in the memory cell in the second write operation depending on how many times the sequence of operations is performed.

### Additional Embodiment 4

A method for performing an overall read operation on a memory cell of a semiconductor storage device comprises the limitations of Explicitly Included Embodiment 1 and further comprises: varying a pulse width of a program voltage applied to the memory cell in the second write operation depending on how many times the sequence of operations is performed.

### Additional Embodiment 5

A method for performing an overall read operation on a memory cell of a semiconductor storage device comprises the limitations of Explicitly Included Embodiment 1 and further comprises: consecutively performing the verify read operation in an nth round (n is an integer not less than 1) of performing the sequence of operations and the second write operation in an (n+1)th round of performing the sequence of operations.

### Additional Embodiment 6

A method for performing an overall read operation on a memory cell of a semiconductor storage device comprises the limitations of Explicitly Included Embodiment 1 and further comprises: consecutively performing the second read operation and the second write operation of a first round of the sequence of operations.

### Additional Embodiment 7

A method for performing an overall read operation on a memory cell of a semiconductor storage device comprises the limitations of Explicitly Included Embodiment 1 and further comprises: ending the overall read operation based on an mth round (m is an integer not less than 2) of the sequence of operations having been performed.

While certain embodiments have been described, these embodiments have been presented by way of example only, and are not intended to limit the scope of the invention. Indeed, the novel devices and methods described herein may be embodied in a variety of other forms; furthermore, various omissions, substitutions and changes in the form of the embodiments described herein may be made without departing from the spirit of the invention. The accompanying claims and their equivalents are intended to cover such forms or modification as would fall within the scope and spirit of the invention.

What is claimed is:

1. A semiconductor storage device comprising:
a memory cell that includes a switching element and a variable resistance element; and
a control circuit configured to, as part of performing an overall read operation:
perform a first read operation on the memory cell to detect a first voltage and determine first data stored in the memory cell from the detected first voltage,
perform a first write operation on the memory cell after the first read operation to write second data to the memory cell,
perform a second read operation on the memory cell after the first write operation to detect a second voltage and determine the second data stored in the memory cell from the detected second voltage,
compare the first data and the second data based on the first voltage and the second voltage to determine a value of the first data,
perform a sequence of operations when the first data and the second data are different, the sequence of operations including a second write operation on the memory cell to write the first data to the memory cell, and a verify read operation performed on the memory cell after the second write operation that detects a third voltage and determines third data stored in the memory cell from the detected third voltage,
compare either the first data and the third data based on the first voltage and the third voltage or the second data and the third data based on the second voltage and the third voltage,
end the overall read operation when the first data and the third data are the same or when the second data and the third data are different, and
repeat the sequence of operations when the first data and the third data are different or when the second data and the third data are the same.

2. The semiconductor storage device of claim 1, wherein the control circuit is further configured to:
vary a program voltage applied to the memory cell in the second write operation depending on how many times the sequence of operations is performed.

3. The semiconductor storage device of claim 1, wherein the control circuit is further configured to:
vary an amount of current caused to flow in the memory cell in the second write operation depending on how many times the sequence of operations is performed.

4. The semiconductor storage device of claim 1, wherein the control circuit is further configured to:
vary a pulse width of a program voltage applied to the memory cell in the second write operation depending on how many times the sequence of operations is performed.

5. The semiconductor storage device of claim 1, wherein the control circuit is further configured to:
consecutively perform the verify read operation in an nth round (n is an integer not less than 1) of performing the sequence of operations and the second write operation in an (n+1)th round of performing the sequence of operations.

6. The semiconductor storage device of claim 5, wherein the switching element is a snap-back selector.

7. The semiconductor storage device of claim 1, wherein the control circuit is further configured to:
consecutively perform the second read operation and the second write operation of a first round of the sequence of operations.

8. The semiconductor storage device of claim 7, wherein the switching element is a snap-back selector.

9. The semiconductor storage device of claim 1, wherein a direction in which the control circuit applies voltage to the memory cell in each of the first read operation, the second read operation, and the verify read operation is opposite to a direction in which the control circuit applies voltage to the memory cell in the first write operation.

10. The semiconductor storage device of claim 1, wherein the control circuit is further configured to:
end the overall read operation based on an mth round (m is an integer not less than 2) of the sequence of operations having been performed.

11. The semiconductor storage device of claim 1, wherein the variable resistance element includes a first ferromagnetic layer, a second ferromagnetic layer, and an insulating layer between the first ferromagnetic layer and the second ferromagnetic layer.

12. The semiconductor storage device of claim 1, wherein the switching element is a two-terminal switching element.

13. A method for performing an overall read operation on a memory cell of a semiconductor storage device, the method comprising:
performing a first read operation on the memory cell to detect a first voltage and determine first data stored in the memory cell from the detected first voltage;
performing a first write operation on the memory cell after the first read operation to write second data to the memory cell;
performing a second read operation on the memory cell after the first write operation to detect a second voltage and determine the second data stored in the memory cell from the detected second voltage;
comparing the first data and the second data based on the first voltage and the second voltage to determine a value of the first data;
determining that the first data and the second data are different;
performing a sequence of operations in response to determining that the first data and the second data are different, the sequence of operations including a second write operation on the memory cell to write the first data to the memory cell, and a verify read operation performed on the memory cell after the second write operation that detects a third voltage and determines third data stored in the memory cell from the detected third voltage;
comparing either the first data and the third data based on the first voltage and the third voltage or the second data and the third data based on the second voltage and the third voltage;
determining that the first data and the third data are different or that the second data and the third data are the same; and
repeating the sequence of operations in response to determining that the first data and the third data are different or that the second data and the third data are the same.

14. The method of claim 13, further comprising:
varying a program voltage applied to the memory cell in the second write operation depending on how many times the sequence of operations is performed.

15. The method of claim 13, further comprising:
varying an amount of current caused to flow in the memory cell in the second write operation depending on how many times the sequence of operations is performed.

16. The method of claim 13, further comprising:
varying a pulse width of a program voltage applied to the memory cell in the second write operation depending on how many times the sequence of operations is performed.

17. The method of claim 13, further comprising:
consecutively performing the verify read operation in an nth round (n is an integer not less than 1) of performing the sequence of operations and the second write operation in an (n+1)th round of performing the sequence of operations.

18. The method of claim 13, further comprising:
consecutively performing the second read operation and the second write operation of a first round of the sequence of operations.

19. The method of claim 13, further comprising:
ending the overall read operation based on an mth round (m is an integer not less than 2) of the sequence of operations having been performed.

20. The method of claim 13, wherein it is determined that the first data and the third data are different based on the first voltage and the third voltage, the method further comprising:
repeating the sequence of operations in response to determining that the first data and the third data are different.
